(19) United States
(12) Patent Application Publication
(10) Pub. No.: US 2017/0212409 A1
(43) Pub. Date: Jul. 27, 2017

(54) CAMERA MODULE HAVING A SIDE ACTUATOR

(71) Applicant: MDPULSE CO., LTD., Gumi-si (KR)

(72) Inventor: Jin Kuk KIM, Cheonan-si (KR)

(73) Assignee: MDPULSE CO., LTD., Gumi-si (KR)

(21) Appl. No.: 15/044,570

(22) Filed: Feb. 16, 2016

(30) Foreign Application Priority Data
Jan. 22, 2016 (KR) 10-2016-0008251

(51) Int. Cl. G03B 13/36; G01R 33/07; H02K 41/035; G02B 13/00; G02B 7/09

(52) U.S. Cl. CPC G03B 13/36; G02B 13/001; G02B 7/09; H02K 41/0354; G01R 33/072

(57) ABSTRACT

A camera module is provided, comprising: a mover mounted with a lens; a stator movably supporting the mover to an optical direction of the lens; a side actuator mounted with a coil moving the mover to the optical direction relative to the stator and a magnet; a ball interposed between the mover and the stator; and rails, each rail provided at the mover and the stator to guide a linear travel of the ball, wherein the side actuator is lopsidedly arranged at each one side of the stator and the mover.

Pursuant to 35 U.S.C.§119 (a), this application claims the benefit of earlier filing date and right of priority to Korean Patent Application No. 10-2016-0008251, filed on Jan. 22, 2016, the contents of which are hereby incorporated by reference in their entirety.

### BACKGROUND OF THE DISCLOSURE

Field

The teachings in accordance with the exemplary embodiments of this present disclosure generally relate to a camera module provided with a coil configured to provide a driving force relatively moving a mover and a stator.

Background

The recent market trend of mobile phone industries has changed in its aspect due to competitiveness of control technologies for realizing an accurate image quality while increasing the number of pixels. A compact digital camera module differentiated to have a high resolution requires an auto focusing function in order to realize an accurate image quality despite being of small size.

Although the auto focusing function is already generalized in the conventional digital cameras, it is still difficult to realize the auto focusing function in a compact digital camera module miniaturized in terms of length/breadth size to within several mm. In order to realize the auto focusing function in a compactly miniaturized camera module, a renovating improvement in a driving mechanism including an actuator is required.

Furthermore, there is a need to minimize an interference with other members relative to a magnetic field generated by a coil providing a driving force of the auto focusing function. Although the Korea registered patent publication No. 0649490 discloses a latch method solenoid type actuator, no measure to prevent a magnetic field generated from a coil from affecting other members is disclosed.

### CITED REFERENCE DOCUMENT

[Patent Document] Korea Registered Patent Publication No. 0649490

Technical subjects to be solved by the present disclosure are not restricted to the above-mentioned description, and any other technical problems not mentioned so far will be clearly appreciated from the following description by the skilled in the art.

### SUMMARY OF THE DISCLOSURE

The present disclosure is provided to solve the aforementioned problems and it is an object of the present disclosure to provide a camera module configured to limit an influence of magnetic field affecting other members mounted on a terminal.

In one general aspect of the present disclosure, there is provided a camera module, comprising:

a mover mounted with a lens;
a stator movably supporting the mover to an optical direction of the lens;
a side actuator mounted with a coil moving the mover to the optical direction relative to the stator and a magnet;
a ball interposed between the mover and the stator; and
rails, each rail provided at the mover and the stator to guide a linear travel of the ball, wherein the side actuator is lopsidedly arranged at each one side of the stator and the mover.

Preferably, but not necessarily, the ball and rail may be lopsidedly arranged to a side where the side actuator is arranged based on the optical axis of lens.

Preferably, but not necessarily, the stator may take a shape of a square pillar, the coil may be arranged only at one lateral surface of four lateral surfaces of the stator forming the square pillar, and the magnet may be arranged only at one lateral surface of the mover opposite to the coil.

Preferably, but not necessarily, the stator may have a first surface, a second surface, a third surface and a fourth surface, corresponding to four lateral surfaces, when a magnetic member affected by a magnetic force of the coil is mounted on a main board of a terminal along with the stator, where the first surface, the second surface and the third surface face the magnetic member, and the stator is mounted on the main board to allow the coil to be lopsidedly arranged on a fourth surface side.

Preferably, but not necessarily, the camera module may further comprise a yoke sucking the mover to a stator side, wherein the magnet is mounted on the mover, the yoke is mounted at one side of the stator arranged with the coil to allow facing the magnet, the mover sucked to the stator side by the yoke is moved to the optical axis direction by interaction between the coil and the magnet, and the ball, the rail, the yoke and the magnet are lopsidedly arranged to one side based on an optical axis of the lens.

Preferably, but not necessarily, the camera module may further comprise a substrate mounted with the coil, wherein the coil is formed in a closed curve pillar shape having a through hole by a winding of a conductive wire having one distal end and the other distal end, a bottom surface of the coil is mounted on the substrate, a passage part passing the one distal end or the other distal end of the conductive wire is provided on the substrate, the passage part is configured in a manner such that a part of the substrate is cut off, or a thickness of the substrate is partially thinned out, and the one distal end or the other distal end of the conductive wire is extracted toward a periphery side of the coil through the passage part.

Preferably, but not necessarily, a first hole may be formed between an inner circumference and the passage part, a second hole is formed between an outer circumference and the passage part, and the one distal end or the other distal end of the conductive wire may pass out through the first hole to escape through the second hole.

Preferably, but not necessarily, the camera module may further comprise a substrate mounted with the coil, wherein the coil is formed in a closed curve pillar shape having a through hole by a winding of a conductive wire having one distal end and the other distal end, a bottom surface of the coil is mounted on the substrate, the one distal end of the conductive wire is extracted from an inner circumference of the coil positioned with the through hole, the other distal end of the conductive wire is extracted from an outer circumference of the coil, and the one distal end or the other distal end of the conductive wire is extracted from the bottom surface of the coil.

Preferably, but not necessarily, the camera module may further comprise a substrate mounted with the coil, wherein the coil is formed in a closed curve pillar shape having a through hole by a winding of a single strand of conductive wire, a bottom surface of the coil is mounted on the substrate, a one distal end of the conductive wire is extracted from an inner circumference of the coil positioned with the through hole, the substrate is provided with a passage part passed by the conductive wire, the passage part is extended from the through hole positioned with the one distal end of the conductive wire extracted from an inner circumference of the coil to an outer circumference of the coil, and the one distal end of the conductive wire passes through the passage part to be extracted to an outer circumference side of the coil.

Preferably, but not necessarily, the camera module may further comprise a substrate mounted with the coil, wherein the coil is formed by being wound with an electrically conductive wire in a closed curve shape, one surface of the substrate opposite to the coil is laminated with a cover lay with a thickness more than a diameter of the conductive wire, the cover lay is provided with a passage part corresponding to a groove passed by the conductive wire, and the passage part is extended from the cover lay to an area opposite to at least an outer circumference of the coil from an area opposite to the through hole of the coil.

Preferably, but not necessarily, the camera module may further comprise:

a magnet provided on a surface opposite to the coil from the mover;
a substrate mounted with the coil;
a Hall sensor mounted on the substrate to detect a change in magnetic field of the magnet induced by a relative movement of the mover and the stator, wherein an electric signal applied to the coil and a detection signal of the Hall sensor flow on the substrate, a through hole having a diameter larger than a diameter of the Hall sensor is provided at a center of the coil, and the Hall sensor is arranged at a center of the through hole where a magnetic field generated by the coil is offset by the electric signal.

### Advantageous Effects

A side actuator providing a driving force relatively moving a mover and a stator is lopsidedly arranged only at one side of the stator according to the present disclosure, whereby a measure of so arranging a camera module as to affect a less influence of magnetic field to other members can be provided, when the camera module is mounted on a main board of a terminal along with the other members including a microphone affected by the magnetic field.

Furthermore, a coil can be directly mounted on a substrate mounted on a camera module in order to minimize volume of the camera module according to the present disclosure. A distal end of a conductive wire forming a coil may be extracted into an inner circumference of the coil when the coil is directly mounted on the substrate. A passage part can be provided to allow a distal end of the conductive wire extracted to an outer circumference can escape the coil to pass out to the outer circumference. The coil is fastened to the substrate in a completely stuck state by the passage part to surely prevent the coil from being detached from the substrate due to an external shock.

### BRIEF DESCRIPTION OF DRAWINGS

FIG. 1 is a schematic perspective view illustrating a camera module according to the present disclosure.

FIG. 2 is an exploded perspective view illustrating a camera module according to the present disclosure.

FIG. 3 is a schematic view illustrating a substrate and a coil according to the present disclosure.

FIG. 4 is a schematic view illustrating a state of a coil mounted on a substrate according to the present disclosure.

FIG. 5 is a schematic view illustrating a passage part according to the present disclosure.

FIG. 6 is a schematic view illustrating another passage part according to the present disclosure.

FIG. 7 is a schematic view illustrating a Hall sensor according to the present disclosure.

### DETAILED DESCRIPTION OF THE DISCLOSURE

Features and advantages of the exemplary embodiments will be or will become apparent to one of ordinary skill in the art upon examination of the following figures and detailed description. In describing the present disclosure, certain layers, sizes, shapes, components or features may be exaggerated for clarity and convenience. Accordingly, the meaning of specific terms or words used in the specification and claims should not be limited to the literal or commonly employed sense, but should be construed or may be different in accordance with the intention of a user or an operator and customary usages. Therefore, the definition of the specific terms or words should be based on the contents across the specification.

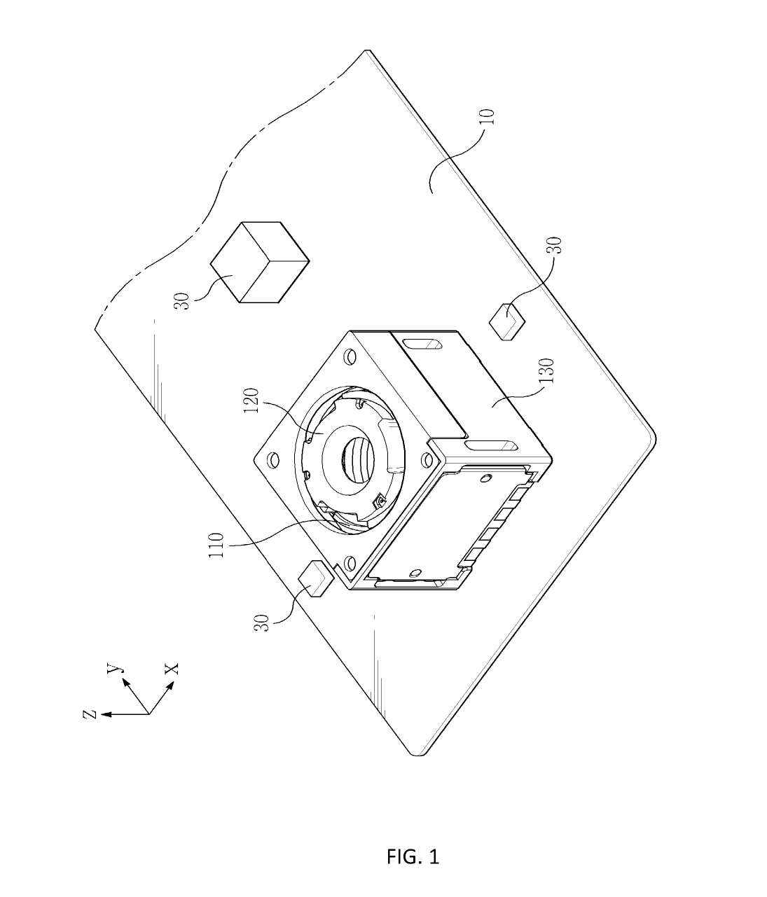

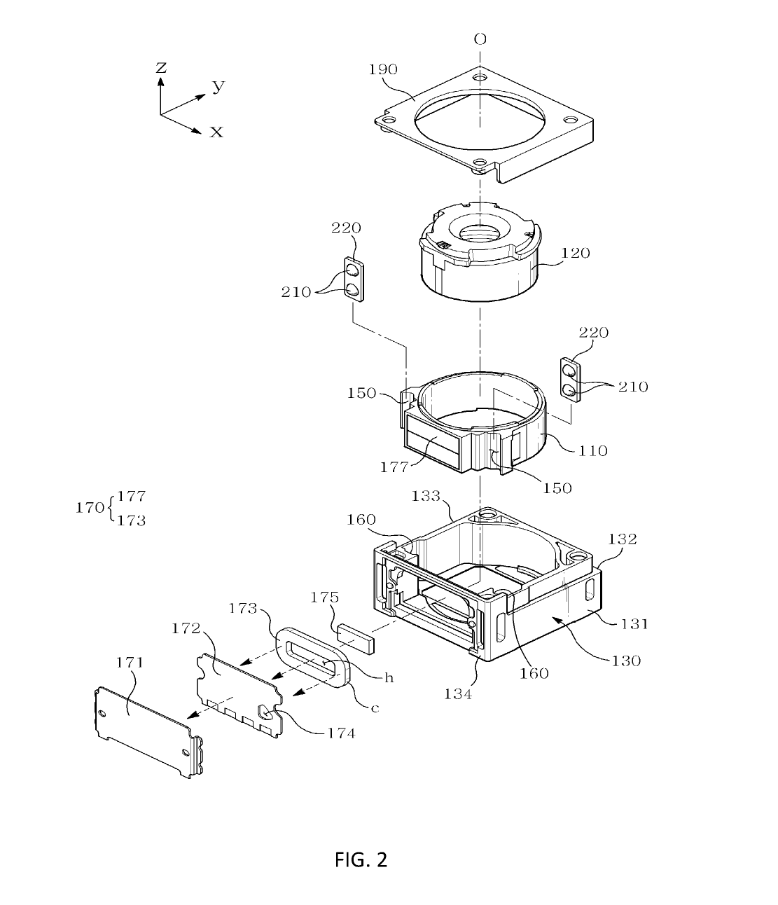

FIG. 1 is a schematic perspective view illustrating a camera module according to the present disclosure, and FIG. 2 is an exploded perspective view illustrating a camera module according to the present disclosure.

The illustrated camera module may include a moving part (hereinafter referred to as ‘mover’, 110), a stationary part (hereinafter referred to as ‘stator’, 130), a side actuator (170), a ball (210) and a rail. The mover (110) may be fixedly mounted with a lens (not shown). When the lens is installed inside a body tube (120), the mover (110) may be fixedly installed with the body tube (120). In the present disclosure, the term of optical axis means an imaginary axis on which an optical image incident from a subject to a camera module advances, and the optical axis is z axis as illustrated in the drawings.

The stator (130) to prevent foreign objects from coming in may be covered by a cover (190). The mover (110) may be moved to an optical axis during auto focusing by the side actuator (170) including a coil (173) and a magnet (177). One of the coil (173) and the magnet (177) may be installed on the mover (110), and the other may be installed on the stator (130). The stator (130) may movably support the mover (110) to an optical axis direction of the lens. Movably supporting the mover (110) to an optical axis direction using other means than an elastic member is advantageous to tilting restriction and low power.

The camera module according to the present disclosure may use a ball (210) in order to reduce consumption of power for moving the mover (110) to the optical axis direction and to prevent an inclined tilt. The ball (210) may be interposed between the mover (110) and the stator (130). The ball (210) may be provided in a plural number each at a mutually different position along an optical axis direction (z axis) in order to prevent the inclined tilt where the mover (110) is inclined to an optical axis.

A retainer (220) may be provided in order to constantly maintain a gap among a plurality of balls (210) arranged along the optical axis direction. The ball (210) may be provided in a plural number each at a mutually different position along a horizontal direction (x axis) in order to prevent a horizontal tilt where the mover (110) is inclined to a horizontal direction perpendicular to the optical axis.

A rail may be formed between the mover (110) and the stator (130) to guide a linear travel of the ball (210). To be more specific, a first rail (150) provided at the mover (110) and a second rail (160) provided at the stator (130) may be so formed as to face each other. The first rail (150) may be so formed as to allow a relative movement of the ball (210) relative to the mover (110) to an optical axis direction.

For example, the first rail (150) may include a groove formed at one surface of the mover (110) opposite to the stator (130) and extended along an optical axis direction. The ball (210) may roll-contact the first rail (150), and may relatively move to the mover (110) when the mover (110) and the stator (130) relatively move. The second rail (160) may be so formed as to allow the ball (210) to relatively move relative to the stator (130) to an optical axis direction.

For example, the second rail (160) may include a groove formed at one surface of the stator (130) opposite to the first rail (150) and extended along an optical axis direction. The ball (210) may roll-contact the second rail (160), and may relatively move to the stator (130) when the mover (110) and the stator (130) relatively move.

According to the first rail (150), the second rail (160) and the ball (210), the mover (110) and the stator (130) may relatively move to an optical axis direction while being guided to the roll-contact of the ball (210) interposed between the mover (110) and the stator (130). Thus, power consumption necessary for relative movement between the mover (110) and the stator (130) may be improved because the relative movement is realized through the roll-contact.

The camera module may be installed on a terminal along with other members. At this time, the camera module mounted with the coil (173) and the magnet (177) may be generated with a magnetic field obstructing operations of other members. Thus, it is necessary for the camera module to be so arranged as to affect a less influence on other members inside the terminal. However, when the magnetic field is generated from all surfaces of the camera module, the camera module may affect an influence on other members no matter how the camera module is installed inside the terminal.

The side actuator (170) included in the camera module according to the present disclosure in order to exert a less influence of the magnetic field on other members may be lopsidedly arranged to only one side of the stator (130) and the mover (110) on a plan surface perpendicular to an optical axis. The ball (210) and the rail may be also lopsidedly arranged to a side arranged by the side actuator (170) based on the optical axis of the lens in order to smoothly and relatively move the mover (110) and the stator (130) by the side actuator (170) arranged lopsidedly to one side.

Assuming a comparative exemplary embodiment in which the mover is supported by the stator by an elastic member such as a leaf spring. In order to prevent an inclined tilt inclined to an optical axis and to move the mover to an optical axis direction in the comparative exemplary embodiment, the side actuator (170) may be installed at least on both left and right sides of optical axis (0). Meantime, a relative movement of the mover (110) and the stator (130) may be realized using the ball (210) and each rail (150, 160) lopsidedly arranged to one side according to the present disclosure. Thus, it may be sufficient that the side actuator (170) is installed only at one side where the ball (210) is installed based on the optical axis (0).

When a first direction (x axis direction) perpendicular to the optical axis (0) and a second direction (y axis direction) are defined, a plurality of balls (210) may be arranged at mutually different positions to the first direction. At this time, the side actuator (170) may be arranged at one side of the stator (130) to the second direction perpendicular to the first direction. The stator (130) may form an external look of a camera module. The stator (130) may take a square pillar shape in order to minimize the overall size of the camera module. At this time, the coil (173) may be arranged only one lateral surface among the four lateral surfaces of the stator (130) forming the square pillar. The magnet (177) may be arranged only at one side surface of the mover (110) opposite to the coil (173).

To be more specific, when a magnetic member (30) influenced by a magnetic force of the coil (173) is installed on a main board (10) of the terminal along with the stator (130), the stator (130) may have a first surface (131), a second surface (132), a third surface (133) and a fourth surface (134) corresponding to four lateral surfaces. At this time, the first surface (131), the second surface (132) and the third surface (133) may face the magnetic member (30). At this time, the stator (130) may be installed on the main board (10) in order to be lopsidedly arranged to a fourth surface (134) side.

The magnetic member (30) may include members intrinsically changeable in function by a magnetic force such as a microphone, a speaker and a vibration motor. When the magnetic member (30) is installed on the main board (10) of the terminal, it is preferable that the stator (130) be arranged at a position maximally distanced from the magnetic member (30). However, when the size of the main board (10) is restricted, the magnetic member (30) may be inevitably installed at a vicinity of the stator (130). In this case, the magnetic member (30) may be influenced by the magnetic field of the side actuator (170).

When the stator (130) is rotated based on the optical axis (0) as a rotation shaft according to the present disclosure, a discrete distance between the side actuator (170) and magnetic member (30) may be changed in response to a rotation angle. Thus, a user may install the stator (130) on the main board (10) under a state of the stator (130) being rotated at a rotation angle less affecting to the magnetic member (30). When the stator (130) is arranged like this, the side actuator (170) is positioned at a fourth surface (134) side of the stator (130) not opposite to the magnetic member (30), and the magnetic member (30) may be less affected by the influence of the side actuator (170).

The camera module according to the present disclosure may include a yoke (171) sucking the mover (110) to the stator (130) side. The mover (110) and the stator (130) may be stuck together by a suction force of the yoke (171) to prevent the ball (210) from free-falling by self-weight of the ball. The yoke (171) may include a magnetic substance applied with an attractive force of the magnet (177) included in the side actuator (170). The mover (110) installed with the magnet (177) may be sucked toward the stator (130) installed with the yoke (171) by the attractive force interacting between the yoke (171) and the magnet (177).

The yoke (171) may be installed at one side of the stator (130) arranged with the coil (173) in order to face the magnet (177).

When material of the yoke (171) includes a metal having a substance of being attracted to the magnet (177), the yoke (171) may form a fourth surface (134) of the stator (130) corresponding to a one side wall surface of the stator (130) and non-opposite to the magnetic member (30). In order to protect the fourth surface (134), the yoke (171) may be formed in a plate shape.

The mover (110) sucked to a stator (130) side by the yoke (171) may be moved to an optical axis direction by the interaction between the coil (173) and the magnet (177). At this time, the ball (210, the rail, the yoke (171) and the magnet (177) may be in a state of being lopsidedly arranged to one side based on the optical axis (0) of the lens. A one surface of the yoke (171) opposite to the mover (110) may be installed with a substrate (172). The substrate (172) may be installed with a coil (173) forming the side actuator (170). A through hole (h) may be formed at a center of the coil (173) wound with an electric conducting wire (176) in a closed curve shape. A Hall sensor (175) may be installed at a center of the through hole in order to detect a change in magnetic field of the magnet (177). The change in magnetic field of the magnet (177) detected by the Hall sensor (175) may be used to grasp a relative position relative of the mover (110) to the stator (130).

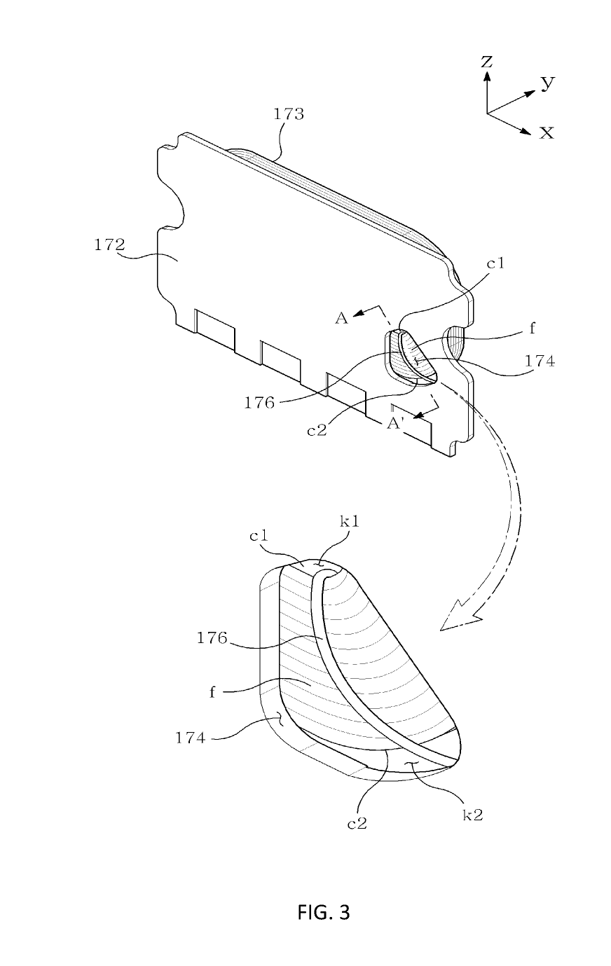

FIG. 3 is a schematic view illustrating a substrate (172) and a coil (173) according to the present disclosure.

The coil (173) may be a winding of a conductive wire (176) having a one distal end and the other distal end in a closed curve pillar shape formed with a through hole (h). At this time, the coil (173) may be installed on the substrate (172) in a state of being stuck at a bottom surface (f) to the substrate (172). The substrate (172) may be provided with a passage part (174) passed by a distal end or the other end of the conductive wire (176).

The passage part (174) may be formed by cutting a part of the substrate (172) or by thinning a part of the thickness of the substrate (172). At this time, the one distal end or the other end of the conductive wire (176) may be extracted to an outer circumference c2 side of the coil (173) through the passage part (174). At this time, a first hole k1 may be formed between the inner circumference c1 of the coil and the passage part (174). Furthermore, a second hole k2 may be formed between the outer circumference c2 of the coil and the passage part (174). The one distal end or the other distal end of the conductive wire (176) may be escape to the second hole k2 by passing through the first hole k1.

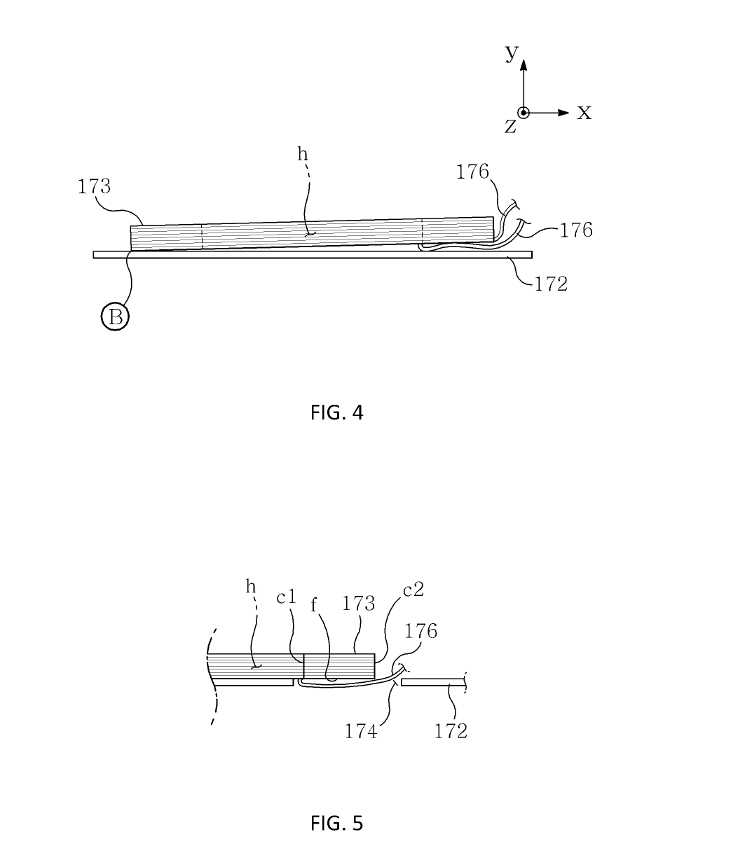

FIG. 4 is a schematic view illustrating a state of a coil (173) mounted on a substrate (172) according to the present disclosure.

A distal end of the conductive wire (176) may be extracted from the inner circumference c1 of the coil (173) positioned by the through hole (h). Meanwhile, the other distal end of the conductive wire (176) may be extracted from an outer circumference c2 of the coil (173). At this time, the one distal end and the other distal end of the conductive wire (176) are preferably extracted from a bottom surface (f) of the coil (173). A distal end of the conductive wire (176) may be electrically connected to a terminal provided at the substrate (172). At this time, a relevant terminal may be arranged at the outer circumference c2 side of the coil (173).

If the one distal end or the other distal end of the conductive wire (176) is extracted from an upper surface of the coil (173) opposite to the magnet (177), a part of the conductive wire (176) may have no choice by to be connected to a terminal of the substrate (172) crisscrossing an air. The conductive wire (176) installed in the air may be weak to an external shock and difficult to be handled, such that the conductive wire (176) installed in the air would be better be ruled out. Thus, it would be better to extract both distal ends of the conductive wire (176) from the bottom surface (f) of the coil (173).

At this time, a distal end of the conductive wire (176) extracted from the through hole (h) side of the coil (173) may be an issue. The distal end of the conductive wire (176) extracted from the inner circumference c1 of the coil (173) may be extracted to the outer circumference c2 side of the coil (173) by passing through the coil (173) and the substrate (172) order to rule out the state of the conductive wire (176) being suspended in the air. When the conductive wire (176) is passed through the coil (173) of the substrate (172), a one side of the coil (173) passed by the conductive wire (176) has no choice but to be lifted from the substrate 172) by the conductive wire (176). Thus, the entire bottom surface of the coil (173) cannot be stuck to the substrate (172), and only a part of corner portion B of the coil (173) is adhered to the substrate (172), whereby an adhesive state between the substrate (172) and the coil (173) may be not good. Furthermore, the coil (173) may be installed to the substrate (172) in an inclined state.

The substrate (172) may be arranged in parallel with the magnet (177). Thus, when the coil (173) is inclined relative to the substrate (172), the coil (173) and the magnet (177) cannot be arranged in parallel. The coil (173) and the magnet (177) mutually arranged in inclined state may have a difficulty in evenly generating a driving force relatively moving the mover (110) and the stator (130). It is preferable that the bottom surface (f) of the coil (173) be tightly contacted to the substrate (172) in order to securely install the bottom surface (f) of the coil (173) to the substrate (172) and to allow an upper surface of the coil (173) to be in parallel with the magnet (177).

A distal end of the conductive wire (176) extracted from the inner circumference c1 of the coil (173) in order to tightly contact the bottom surface (f) of the coil (173) to the substrate (172), and escaped to the outer circumference C2 side of the coil (173) needs to be escaped to a separately provided path. Here, the passage part (174) may be used as the separate path.

FIG. 5 is a schematic view illustrating a passage part (174) according to the present disclosure FIG. 5 illustrates a cross-sectional view cut along line A-A′ of FIG. 3. The bottom surface (f) of the coil (173) is installed on the substrate (172), a distal end of the conductive wire (176) may be extracted from the inner circumference c1 of the coil (173) positioned with the through hole. The substrate (172) may be provided with a passage part (174) passed by the conductive wire (176). The passage part (174) may be formed by cutting a part of the substrate (172), and may include a hole formed at the substrate (172).

The passage part (174) may be extended from the through hole (h) positioned with the one distal end of the conductive wire (176) extracted from the inner circumference c1 of the coil (173) to the outer circumference c2 of the coil (173). At this time, the one distal end of the conductive wire (176) may be extracted to the outer circumference c2 side of the coil (173) by passing through the passage part (174).

According to the passage part (174), all the areas except for the area contacting the passage part (174) in the bottom surface (f) of the coil (173) may tightly contact the substrate (172). Thus, the coil (173) can be securely installed on the substrate (172) and may be arranged in parallel with the substrate (172) and the magnet (177). Furthermore, when the thickness of the substrate (172) is greater than a diameter of the one distal end of the conductive wire (176), the substrate (172) can tightly contact an inner lateral surface of the yoke (171) or the stator (130) without any particular problems.

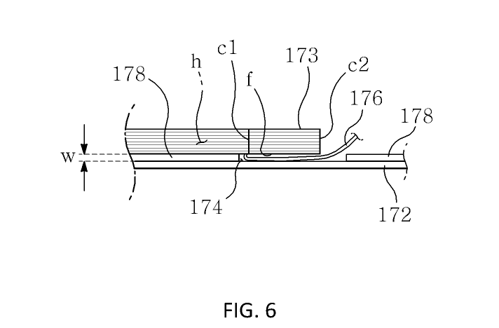

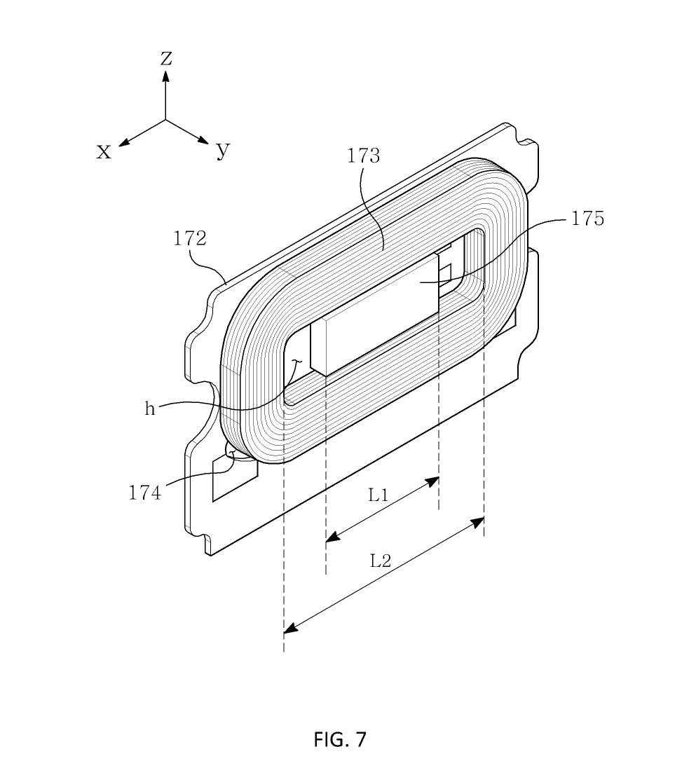

FIG. 6 is a schematic view illustrating another passage part (174) according to the present disclosure.

One surface of the substrate (172) opposite to the coil (173) may be laminated with a cover lay (178) with a thickness more than a diameter of the conductive wire (176) forming the coil (173). The cover lay (178) may include a resin layer laminated on the substrate (172) for electrical insulation, flame retardancy, thermal resistance and protection of circuit formed on the substrate (172). The cover lay (178) may be provided with a passage part (174) corresponding to the groove passed by the conductive wire (176).

The passage part (174) may be extended from an area opposite to the through hole (h) of the coil (173) on the cover lay (178) to an area opposite to at least the outer circumference c2 of coil (173). A distal end of the conductive wire (176) extracted from the inner circumference c1 of the coil (173) may escape to the outer circumference c side of the coil (173) by passing through the passage part (174). The one distal end of the conductive wire (176) having escaped to the outer circumference c2 may be electrically connected to a terminal provided on the substrate (172).

The cover lay (178) may be applied when thickness of the substrate (172) is formed smaller than a diameter of the conductive wire (176), or when it is difficult to cut a part of the substrate (172) or to form a hole on the substrate (172).

FIG. 7 is a schematic view illustrating a Hall sensor (175) according to the present disclosure.

The magnet (177) may be provided on a surface opposite to the coil (173) on the mover (110). At this time, a Hall sensor (175) may be provided to detect a change in magnetic field of the magnet induced by relative movement of the mover (110) and the stator (130). It is preferable that the Hall sensor (175) be arranged at a position where the magnetic field change of the magnet (177) is detected but the magnetic field change of the coil (173) is not detected. Furthermore, it is preferable that the Hall sensor (175) be installed on the substrate (172) for input or output of electric signal.

In order to satisfy these conditions, the substrate (172) may be so formed as to allow an electric signal applied to the coil (173) and a detection signal of the Hall sensor (175) to flow. Furthermore, a through hole (h) having a diameter L2 greater than a diameter L1 of the Hall sensor (175) may be provided at a center of the coil (173). At this time, the Hall sensor (175) may be arranged at a center of the through hole (h) where magnetic field generated by the coil (173) is offset by an electric signal. The center of the through hole (h) is positioned opposite to the magnet (177), such that it may be advantageous to detect the magnetic field change of the magnet (177).

Furthermore, the center of the through hole (h) may be a position where the magnetic field of coil (173) is offset or a position where the substrate (172) is exposed. Thus, the Hall sensor (175) arranged at a center of the through hole (h) can surely detect the magnetic field change of the magnet (177), and transmit a detection result to outside through the substrate (172).

Although the camera module has been described and explained according to exemplary embodiments, the present disclosure is not limited to a particular exemplary embodiment but many alternatives, modifications, and variations will be apparent to those skilled in the art within the metes and bounds of the claims.

Therefore, it should be understood that the above-described embodiments are not limited by any of the details of the foregoing description, unless otherwise specified, but rather should be construed broadly within the scope as defined in the appended claims

What is claimed is:

1. A camera module, comprising:
a mover mounted with a lens;
a stator movably supporting the mover to an optical direction of the lens;
a side actuator mounted with a coil moving the mover to the optical direction relative to the stator and a magnet;
a ball interposed between the mover and the stator; and
rails, each rail provided at the mover and the stator to guide a linear travel of the ball, wherein the side actuator is lopsidedly arranged at each one side of the stator and the mover.

2. The camera module of claim 1, wherein the ball and rail are lopsidedly arranged to a side where the side actuator is arranged based on the optical axis of lens.

3. The camera module of claim 1, wherein the stator takes a shape of a square pillar, the coil is arranged only at one lateral surface of four lateral surfaces of the stator forming the square pillar, and the magnet is arranged only at one lateral surface of the mover opposite to the coil.

4. The camera module of claim 1, wherein the stator has a first surface, a second surface, a third surface and a fourth surface, corresponding to four lateral surfaces, when a magnetic member affected by a magnetic force of the coil is mounted on a main board of a terminal along with the stator, where the first surface, the second surface and the third surface face the magnetic member, and the stator is mounted on the main board to allow the coil to be lopsidedly arranged on a fourth surface side.

5. The camera module of claim 1, further comprising a yoke sucking the mover to a stator side, wherein the magnet is mounted on the mover, the yoke is mounted at one side of the stator arranged with the coil to allow facing the magnet, the mover sucked to the stator side by the yoke is moved to the optical axis direction by interaction between the coil and the magnet, and the ball, the rail, the yoke and the magnet are lopsidedly arranged to one side based on an optical axis of the lens.

6. The camera module of claim 1, further comprising a substrate mounted with the coil, wherein the coil is formed in a closed curve pillar shape having a through hole by a winding of a conductive wire having one distal end and the other distal end, a bottom surface of the coil is mounted on the substrate, a passage part passing the one distal end or the other distal end of the conductive wire is provided on the substrate, the passage part is configured in a manner such that a part of the substrate is cut off, or a thickness of the substrate is partially thinned out, and the one distal end or the other distal end of the conductive wire is extracted toward a periphery side of the coil through the passage part.

7. The camera module of claim 6, wherein a first hole is formed between an inner circumference and the passage part, a second hole is formed between an outer circumference and the passage part, and the one distal end or the other distal end of the conductive wire passes out through the first hole to escape through the second hole.

8. The camera module of claim 1, further comprising a substrate mounted with the coil, wherein the coil is formed in a closed curve pillar shape having a through hole by a winding of a conductive wire having one distal end and the other distal end, a bottom surface of the coil is mounted on the substrate, the one distal end of the conductive wire is extracted from an inner circumference of the coil positioned with the through hole, the other distal end of the conductive wire is extracted from an outer circumference of the coil, and the one distal end or the other distal end of the conductive wire is extracted from the bottom surface of the coil.

9. The camera module of claim 1, further comprising a substrate mounted with the coil, wherein the coil is formed in a closed curve pillar shape having a through hole by a winding of a single strand of conductive wire, a bottom surface of the coil is mounted on the substrate, a one distal end of the conductive wire is extracted from an inner circumference of the coil positioned with the through hole, the substrate is provided with a passage part passed by the conductive wire, the passage part is extended from the through hole positioned with the one distal end of the conductive wire extracted from an inner circumference of the coil to an outer circumference of the coil, and the one distal end of the conductive wire passes through the passage part to be extracted to an outer circumference side of the coil.

10. The camera module of claim 1, further comprising a substrate mounted with the coil, wherein the coil is formed by being wound with an electrically conductive wire in a closed curve shape, one surface of the substrate opposite to the coil is laminated with a cover lay with a thickness more than a diameter of the conductive wire, the cover lay is provided with a passage part corresponding to a groove passed by the conductive wire, and the passage part is extended from the cover lay to an area opposite to at least an outer circumference of the coil from an area opposite to the through hole of the coil.

11. The camera module of claim 1, further comprising:
a magnet provided on a surface opposite to the coil from the mover;
a substrate mounted with the coil;
a Hall sensor mounted on the substrate to detect a change in magnetic field of the magnet induced by a relative movement of the mover and the stator, wherein an electric signal applied to the coil and a detection signal of the Hall sensor flow on the substrate, a through hole having a diameter larger than a diameter of the Hall sensor is provided at a center of the coil, and the Hall sensor is arranged at a center of the through hole where a magnetic field generated by the coil is offset by the electric signal.
